(19) United States
(12) Patent Application Publication
(10) Pub. No.: US 2025/0183070 A1
(43) Pub. Date: Jun. 5, 2025

(54) CHAMBER ARRANGEMENTS WITH UPPER AND LOWER PYROMETERS, SEMICONDUCTOR PROCESSING SYSTEMS INCLUDING CHAMBER ARRANGEMENTS, AND MATERIAL LAYER DEPOSITION METHODS

(71) Applicant: ASM IP Holding B.V., Almere (NL)

(72) Inventors: Yanfu Lu, Phoenix, AZ (US); Alexandros Demos, Scottsdale, AZ (US)

(21) Appl. No.: 18/965,804

(22) Filed: Dec. 2, 2024

Related U.S. Application Data
(60) Provisional application No. 63/605,776, filed on Dec. 4, 2023.

(51) Int. Cl. H01L 21/67; C23C 16/458; C23C 16/46; C23C 16/52; H01L 21/66

(52) U.S. Cl. CPC H01L 21/67248; C23C 16/4583; C23C 16/46; C23C 16/52; H01L 22/12

(57) ABSTRACT

A chamber arrangement includes a chamber body having a substrate support arranged therein to seat thereon a substrate during deposition of a material layer onto the substrate, an upper heater element array supported above the chamber body and configured to heat the substrate, and an upper pyrometer supported above the chamber body and operably coupled to the upper heater element array to acquire a substrate temperature measurement of the substrate. A lower heater element array is supported below the chamber body to heat the substrate support and a lower pyrometer is supported below the chamber body and configured to acquire a non-contact substrate support temperature measurement. Semiconductor processing systems, material layer deposition methods, and computer program products are also described.

### CROSS-REFERENCE TO RELATED APPLICATION(S)

This Application claims the benefit of U.S. Provisional Application 63/605,776filed on Dec. 4, 2023, the entire contents of which are incorporated herein by reference.

### FIELD OF INVENTION

The present disclosure generally relates to depositing material layers onto substrates, and more particularly to controlling substrate and substrate support temperature during the deposition of material layers onto substrates.

### BACKGROUND OF THE DISCLOSURE

Material layers are commonly deposited onto substrates during the fabrication of semiconductor devices, such as integrated circuits and power electronics. Material layer deposition is generally accomplished by supporting a substrate within a reactor, heating the substrate, and exposing the substrate to a material layer precursor under environmental conditions selected to cause a material layer onto the substrate. During deposition of the material layer onto the substrate temperature within the reactor may be controlled using a temperature sensor, such as a tactile temperature sensor arranged within the reactor, or a non-contact temperature sensor supported outside of the reactor. While generally satisfactory for their intended purpose, temperature within the reactor may vary in a way not appreciated by either (or both) the tactile or non-contact temperature sensor employed to control temperature within the reactor, potentially causing variation with the material layer deposited onto the substrate.

Such methods and systems have generally been considered suitable for their intended purpose. However, there remains a need in the art for improved chamber arrangements, semiconductor processing systems including such chamber arrangements, and related material layer deposition methods. The present disclosure provides a solution to this need.

### SUMMARY OF THE DISCLOSURE

A chamber arrangement is provided. The chamber arrangement includes a chamber body having a substrate support arranged therein to seat thereon a substrate during deposition of a material layer onto the substrate, an upper heater element array supported above the chamber body and configured to heat the substrate, and an upper pyrometer supported above the chamber body and operably coupled to the upper heater element array to acquire a substrate temperature measurement of the substrate. A lower heater element array is supported below the chamber body to heat the substrate support and a lower pyrometer is supported below the chamber body and configured to acquire a non-contact substrate support temperature measurement.

In addition to one or more of the features described above, or as an alternative, further examples of the chamber arrangement may include a thermocouple abutting the substrate support and configured to acquire a tactile substrate support temperature measurement.

In addition to one or more of the features described above, or as an alternative, further examples of the chamber arrangement may include that the upper pyrometer is operably coupled to only the upper heater element array, and that the lower pyrometer is operably coupled to only the lower heater element array.

In addition to one or more of the features described above, or as an alternative, further examples of the chamber arrangement may include that the upper pyrometer is a first upper pyrometer, that the substrate temperature measurement is a first substrate temperature measurement, and a second upper pyrometer supported above the chamber body configured to acquire a second substrate temperature measurement.

In addition to one or more of the features described above, or as an alternative, further examples of the chamber arrangement may include that the first upper pyrometer is optically coupled to an interior of the chamber body by a first upper pyrometer optical axis intersecting the substrate support, that the second upper pyrometer is optically coupled to the interior of the chamber body by a second upper pyrometer optical axis intersecting the substrate support, and that the lower pyrometer is arranged along a lower pyrometer optical axis intersecting the substrate support.

In addition to one or more of the features described above, or as an alternative, further examples of the chamber arrangement may include that the second upper pyrometer is operably coupled to only the upper heater element array, and that the lower pyrometer is operably coupled to only the lower heater element array.

In addition to one or more of the features described above, or as an alternative, further examples of the chamber arrangement may include a third upper pyrometer supported above the chamber body and configured to acquire a third substrate temperature measurement of the substrate.

In addition to one or more of the features described above, or as an alternative, further examples of the chamber arrangement may include that the third upper pyrometer is optically coupled to an interior of the chamber body by a third upper pyrometer optical axis intersecting the substrate support, that the lower pyrometer is arranged along a lower pyrometer optical axis intersecting the substrate at a location offset from the third upper pyrometer optical axis, and that the third pyrometer is radially intermediate the first pyrometer and the second pyrometer.

In addition to one or more of the features described above, or as an alternative, further examples of the chamber arrangement may include that the third upper pyrometer is operably coupled to only the upper heater element array, and that the lower pyrometer is operably coupled to only the lower heater element array.

A semiconductor processing system is provided. The semiconductor processing system may include a chamber arrangement as described wherein the lower pyrometer is selectable for operable coupling to the lower heater element array; a thermocouple abutting the substrate support and configured to acquire a tactile substrate support temperature measurement, the thermocouple selectable for operable coupling to the lower heater element array; and a controller operatively coupling the upper pyrometer to the upper heater element array and one of the lower pyrometer and the thermocouple to the lower heater element array. The controller may be responsive to instructions recorded on a memory to seat a substrate on the substrate support, heat the substrate, and deposit a material layer onto the substrate. Temperature of the substrate may be controlled using the substrate temperature measurement during deposition of the material layer onto the substrate, temperature of the substrate support may be controlled using the non-contact substrate support temperature measurement during deposition of the material layer when the lower pyrometer is selected, and temperature of the substrate support may be controlled using the tactile substrate support temperature measurement during deposition of the material layer when the thermocouple is selected.

In addition to one or more of the features described above, or as an alternative, further examples of the semiconductor processing system may include that the instructions further cause the controller to receive a lower pyrometer selection, receive the non-contact substrate support temperature measurement from the lower pyrometer, compare the non-contact substrate support temperature measurement to a predetermined substrate support non-contact temperature range, and throttle heating of the substrate support using the lower heater element array when the non-contact substrate support temperature measurement is outside of the predetermined substrate support non-contact temperature range.

In addition to one or more of the features described above, or as an alternative, further examples of the semiconductor processing system may include that the instructions cause the controller to receive a thermocouple selection, receive a tactile substrate support temperature measurement from the thermocouple, compare the tactile substrate support temperature measurement to a predetermined substrate support tactile temperature range, and throttle heating of the substrate support using the lower heater element array when the tactile substrate support temperature measurement is outside of the predetermined substrate support tactile temperature range.

In addition to one or more of the features described above, or as an alternative, further examples of the semiconductor processing system may include that the instructions further cause the controller to operably couple the upper pyrometer to a first upper heater element of the upper heater element array, receive the substrate temperature measurement from the upper pyrometer, compare the substrate temperature measurement to a predetermined substrate temperature range, and throttle heating of the substrate using the first upper heater element when the substrate temperature measurement is outside of the predetermined substrate temperature range.

In addition to one or more of the features described above, or as an alternative, further examples of the semiconductor processing system may include that the upper pyrometer is a first upper pyrometer and the substrate temperature measurement is a first substrate temperature measurement, and that the semiconductor processing system further includes a second upper pyrometer supported above the chamber body and disposed in communication with the controller. The instructions may further cause the controller to operably couple the first upper pyrometer to a first upper heater element of the upper heater element array and the second pyrometer to a second upper heater element of the upper heater element array, receive the first substrate temperature measurement from the first pyrometer and a second substrate temperature measurement from the second upper pyrometer, determine a substrate center-to-edge temperature difference using the first substrate temperature measurement and the second substrate temperature measurement, compare the substrate center-to-edge temperature difference to a predetermined substrate center-to-edge temperature difference range, and throttle heating of the substrate using at least one of the first upper heater element and the second upper heater element of the upper heater element array when the substrate center-to-edge temperature difference is outside of the predetermined substrate center-to-edge temperature difference range.

In addition to one or more of the features described above, or as an alternative, further examples of the semiconductor processing system may include that the upper pyrometer is a first upper pyrometer and that the substrate temperature measurement is a first substrate temperature measurement. The semiconductor processing system may further include a second upper pyrometer supported above the chamber body and disposed in communication with the controller and a third upper pyrometer supported above the chamber body and disposed in communication with the controller. The instructions may further cause the controller to operably couple the first upper pyrometer to a first upper heater element of the upper heater element array, the second pyrometer to a second upper heater element of the upper heater element array, and the third pyrometer to a third upper heater element of the upper heater element array; receive a first substrate temperature measurement from the first pyrometer, a second substrate temperature measurement from the second upper pyrometer, and a third substrate temperature measurement from the third upper pyrometer; determine a substrate center-to-edge temperature gradient using the first substrate temperature measurement, the second substrate temperature measurement and the third substrate temperature measurement; compare the substrate center-to-edge temperature gradient to a predetermined substrate center-to-edge temperature gradient range; and throttle heating of the substrate using at least one of the first upper heater element, the second upper heater element, and the third upper heater element of the upper heater element array when the substrate center-to-edge temperature gradient is outside of the predetermined substrate center-to-edge temperature gradient range.

A material layer deposition method is provided. The method includes, at a chamber arrangement as described above, seating a substrate on the substrate support, heating the substrate, and depositing a material layer onto the substrate. Temperature of the substrate (e.g., substrate temperature) may be controlled using a substrate temperature measurement acquired by the upper pyrometer during deposition of the material layer onto the substrate, temperature of the substrate support (e.g., substrate support temperature) may be controlled using a non-contact substrate support temperature measurement acquired by the lower pyrometer during deposition of the material layer onto the substrate when the lower pyrometer is selected, and temperature of the substrate support is controlled using a tactile substrate support temperature measurement acquired by the thermocouple during deposition of the material layer onto the substrate when the thermocouple is selected.

In addition to one or more of the features described above, or as an alternative, further examples of the method may include that controlling temperature of the substrate support includes receiving the lower pyrometer selection; receiving a non-contact substrate support temperature measurement; comparing the non-contact substrate support temperature measurement to a predetermined substrate support non-contact temperature range; and throttling heating of the substrate support using the lower heater element array when the non-contact substrate support temperature measurement is outside of the predetermined substrate support non-contact temperature range.

In addition to one or more of the features described above, or as an alternative, further examples of the method may include that controlling temperature of the substrate support includes receiving a thermocouple selection, receiving a tactile substrate support temperature measurement, comparing the tactile substrate support temperature measurement to a predetermined substrate support tactile temperature range, and throttling heating of the substrate support using the lower heater element array when the tactile substrate support temperature measurement is outside of the predetermined substrate support tactile temperature range.

In addition to one or more of the features described above, or as an alternative, further examples of the method may include that controlling temperature of the substrate includes operably coupling the upper pyrometer to a first upper heater element of the upper heater element array, receiving the substrate temperature measurement from the upper pyrometer, comparing the substrate temperature measurement to a predetermined substrate temperature range, and throttling heating of the substrate using the first upper heater element when the substrate temperature measurement is outside of the predetermined substrate temperature range.

In addition to one or more of the features described above, or as an alternative, further examples of the method may include that the upper pyrometer is a first upper pyrometer and the substrate temperature measurement is a first substrate temperature measurement. The method may further include operably coupling the first upper pyrometer to a first upper heater element of the upper heater element array and the second pyrometer to a second upper heater element of the upper heater element array, receiving the first substrate temperature measurement from the first pyrometer and a second substrate temperature measurement from a second upper pyrometer, determining a substrate center-to-edge temperature difference using the first substrate temperature measurement and the second substrate temperature measurement, comparing the substrate center-to-edge temperature difference to a predetermined substrate center-to-edge temperature difference range, and throttling heating of the substrate using at least one of the first upper heater element and the second upper heater element of the upper heater element array when the substrate center-to-edge temperature difference is outside of the predetermined substrate center-to-edge temperature difference range.

In addition to one or more of the features described above, or as an alternative, further examples of the method may include operably coupling a third pyrometer to a third upper heater element of the upper heater element array; receiving a third substrate temperature measurement from the third upper pyrometer; determining a substrate center-to-edge temperature gradient using the first substrate temperature measurement, the second substrate temperature measurement and the third substrate temperature measurement; comparing the substrate center-to-edge temperature gradient to a predetermined substrate center-to-edge temperature gradient range; and throttling heating of the substrate using at least one of the first upper heater element, the second upper heater element, and the third upper heater element of the upper heater element array when the substrate center-to-edge temperature gradient is outside of the predetermined substrate center-to-edge temperature gradient range.

In addition to one or more of the features described above, or as an alternative, further examples of the method may include only the lower heater element array, and not the upper heater element array, may be throttled when the substrate support temperature measurement is outside of the predetermined substrate support temperature range or when the tactile substrate support temperature measurement is outside of the predetermined substrate support tactile temperature range.

In addition to one or more of the features described above, or as an alternative, further examples of the method may include that only the upper heater element array, and not the lower heater element array, may be throttle when the substrate temperature measurement is outside of the predetermined substrate temperature range.

In addition to one or more of the features described above, or as an alternative, further examples of the method may include that only the upper heater element array, and not the lower heater element array, may be throttled when the substrate center-to-edge temperature difference is outside of the predetermined substrate center-to-edge temperature difference range.

In addition to one or more of the features described above, or as an alternative, further examples of the method may include that only the upper heater element, and not the lower heater element array, may be throttled when the substrate center-to-edge temperature gradient is outside of the predetermined substrate center-to-edge temperature gradient range.

This summary is provided to introduce a selection of concepts in a simplified form. These concepts are described in further detail in the detailed description of examples of the disclosure below. This summary is not intended to identify key features or essential features of the claimed subject matter, nor is it intended to be used to limit the scope of the claimed subject matter.

### BRIEF DESCRIPTION OF THE DRAWING FIGURES

These and other features, aspects, and advantages of the invention disclosed herein are described below with reference to the drawings of certain embodiments, which are intended to illustrate and not to limit the invention.

FIG. 1 is a schematic diagram of a semiconductor processing system including a chamber arrangement in accordance with the present disclosure, showing a substrate seated within the chamber arrangement during deposition of a material layer onto the substrate;

FIG. 2 is a cross-sectional side view of the chamber arrangement of FIG. 1 according to an example of the present disclosure, showing an upper pyrometer optically coupled to the substrate and a lower pyrometer optically coupled to a substrate support seating the substrate;

FIG. 3 is a block diagram of a material layer deposition method according to the present disclosure, showing operations for controlling temperature of a substrate using an upper pyrometer and temperature of a substrate support using a lower pyrometer or thermocouple;

FIG. 4 is a block diagram of operations to control substrate support temperature according to examples of the method shown in FIG. 3, showing operations to select one of the lower pyrometer and the thermocouple to control temperature of the substrate support; and

FIGS. 5-7 are block diagrams of operations to control substrate temperature according to examples of the method of FIG. 3, showing operations to control temperature of the substrate using one or more upper pyrometers according to examples of the present disclosure.

It will be appreciated that elements in the figures are illustrated for simplicity and clarity and have not necessarily been drawn to scale. For example, the relative size of some of the elements in the figures may be exaggerated relative to other elements to help improve understanding of illustrated embodiments of the present disclosure.

### DETAILED DESCRIPTION OF EXEMPLARY EMBODIMENTS

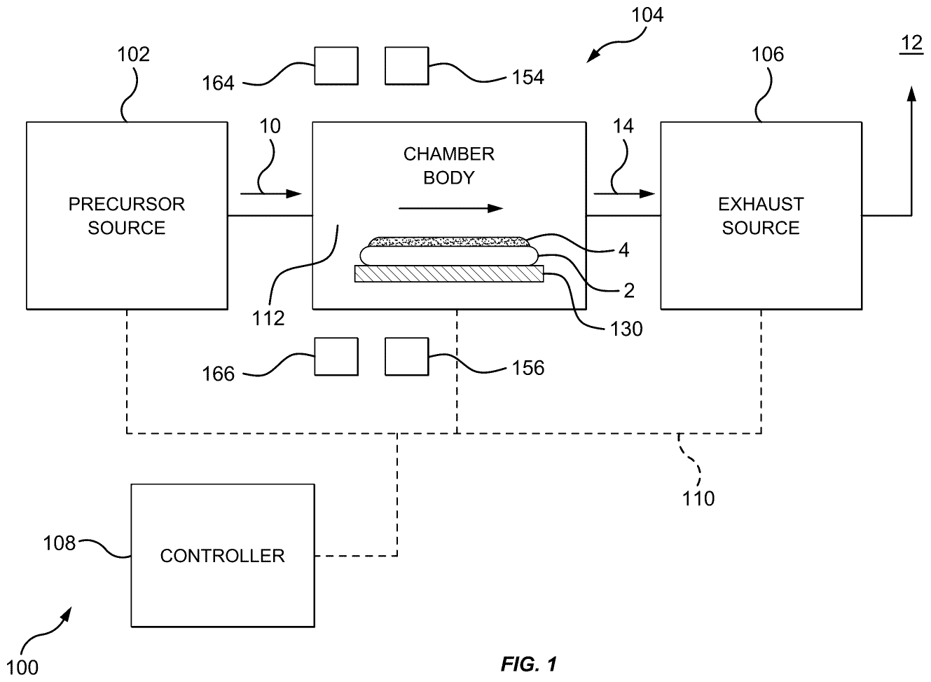

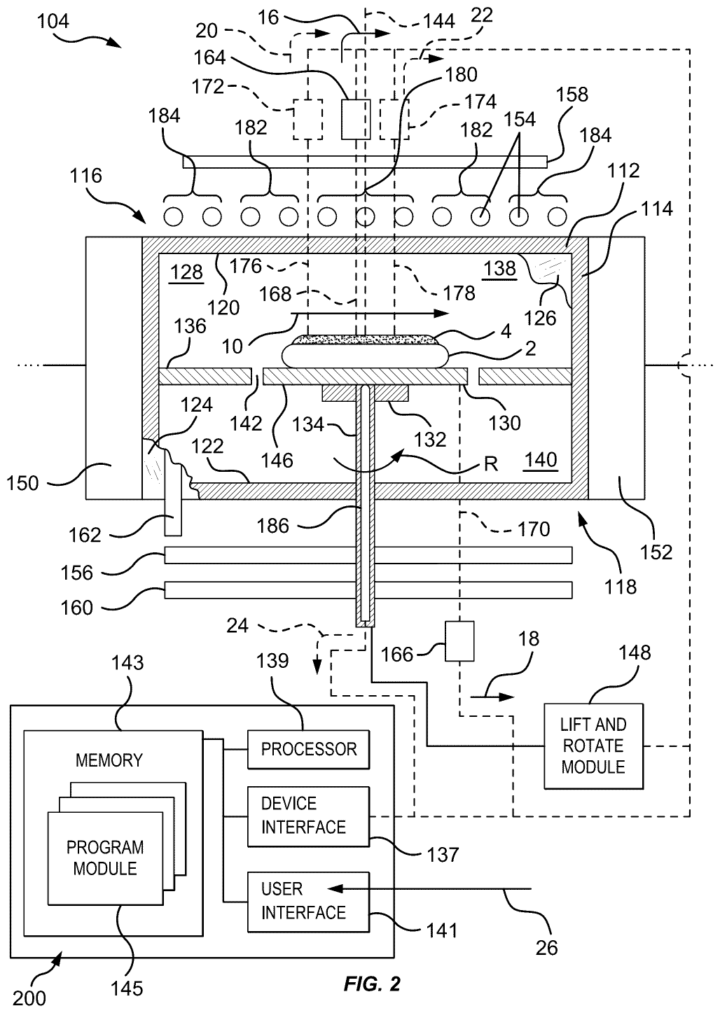

Reference will now be made to the drawings wherein like reference numerals identify similar structural features or aspects of the subject disclosure. For purposes of explanation and illustration, and not limitation, a partial view of an example of semiconductor processing system including a chamber arrangement in accordance with the present disclosure is shown in FIG. 1 and is designated generally by reference character 100. Other examples of chamber arrangements, semiconductor processing systems having chamber arrangements, and methods of depositing material layers onto substrates in accordance with the present disclosure, or aspects thereof, are provided in FIGS. 2-7, as will be described. The systems and methods of the present disclosure may be used to deposit material layers onto substrates during the fabrication of semiconductor devices, such as silicon-containing epitaxial material layers formed during the fabrication of logic and memory semiconductor devices having three-dimensional architectures, though the present disclosure is not limited to any particular type of material layer nor to the fabrication of semiconductor devices in general.

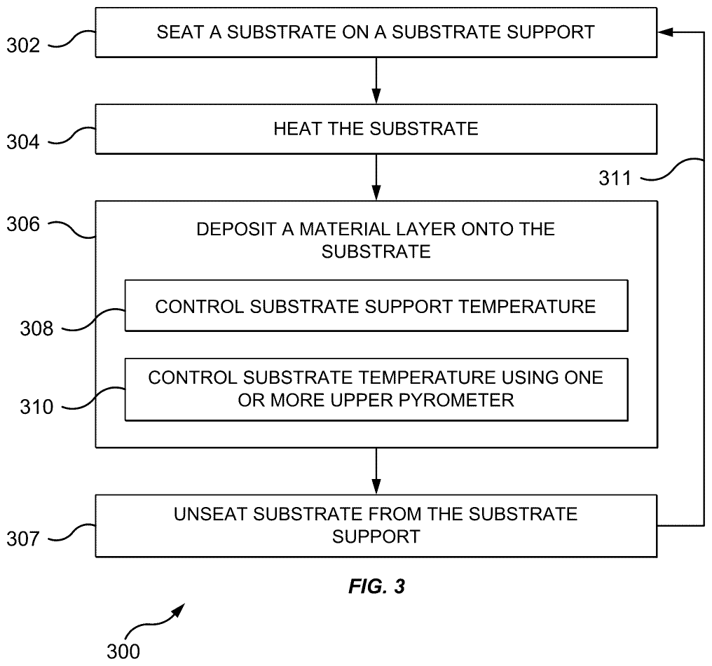

Referring to FIG. 1, the semiconductor processing system 100 is shown. The semiconductor processing system 100 generally includes a precursor source 102, a chamber arrangement 104, an exhaust source 106, and a controller 108. The precursor source 102 is connected to the chamber arrangement 104 and is configured to provide a flow of a material layer precursor 10 to the chamber arrangement 104. The chamber arrangement 104 is connected to the exhaust source 106 and is configured to flow a material layer precursor 10 across a substrate 2 seated within the chamber arrangement 104 under environmental conditions selected to cause a material layer 4 to deposit onto the substrate 2. The exhaust source 106 is in fluid communication with an external environment 12 outside of the semiconductor processing system 100 and is configured to communicate a flow of residual material precursor and/or reaction products 14 to the external environment 12 outside of the semiconductor processing system 100. The controller 108 is operatively connected to the semiconductor processing system 100, for example through a wired or wireless link 110, (e.g., to one or more of the precursor source 102, the chamber arrangement 104, and exhaust source 106) and is configured to deposit the material layer 4 onto the substrate 2 according to operations of a material layer deposition method 300 (shown in FIG. 3), as will be described. In certain examples the exhaust source 106 may include one or more of a vacuum pump and an abatement device, such as a scrubber apparatus.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates may be made from semiconductor materials, including, for example, silicon (Si), silicon germanium (SiGe), silicon oxide (SiO₂), gallium arsenide (GaAs), gallium nitride (GaN), silicon carbide (SiC), phosphorous-doped silicon (SiP), boron-doped silicon germanium (SiGeB), carbon-doped silicon germanium (SiGeC), and aluminum gallium nitride (AlGaN). As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc. A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form. Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

With reference to FIG. 2, it is contemplated that the chamber arrangement 104 include a chamber body 112 with a substrate support 130, an upper heater element array 154, an upper pyrometer 164, a lower heater element array 156, and a lower pyrometer 166. The substrate support 130 is arranged within the chamber body 112 and is configured to seat thereon the substrate 2 during deposition of the material layer 4 onto the substrate 2. The upper heater element array 154 is supported above the chamber body 112 and is configured to heat the substrate 2 (e.g., directly) during deposition of the material layer 4 onto the substrate 2. The upper pyrometer 164 is also supported above the chamber body 112 and operably coupled to the upper heater element array 154 to throttle heating of the substrate 2 by the upper heater element array 154 during deposition using a non-contact substrate temperature measurement, e.g., a substrate temperature measurement 16 (shown in FIG. 2), acquired by the upper pyrometer 164. The lower heater element array 156 and the lower pyrometer 166 are supported below the chamber body 112 and are configured to heat the substrate support 130 (and thereby the substrate 2) and selectable to operably couple the lower pyrometer to the lower heater element array 156 to throttle heating of the substrate 2 using a substrate support temperature measurement acquired by the lower pyrometer 166, e.g., a substrate support temperature measurement 18 (shown in FIG. 2), respectively, during deposition of the material layer 4 onto the substrate 2.

In the illustrated example the chamber arrangement 104 has a single-substrate crossflow architecture and includes the chamber body 112. It is contemplated that the chamber body 112 may be formed at least partially from a transparent material 114, e.g., a material transparent to electromagnetic radiation in an infrared waveband and extend longitudinally between an injection end 116 and an exhaust end 118. The chamber body 112 may further have an upper wall 120, a lower wall 122, a first sidewall 124, and a second sidewall 126. The upper wall 120 may extend longitudinally between the injection end 116 and the exhaust end 118 of the chamber body 112, be formed from the transparent material 114, and be substantially planar in shape. The lower wall 122 may be similar to the upper wall 120 of the chamber body 112 and additionally be spaced apart from the upper wall 120 by an interior 128 (e.g., a hollow interior) of the chamber body 112. The first sidewall 124 and second sidewall 126 may in turn be laterally spaced apart from one another by the interior 128 of the chamber body 112 and further couple the upper wall 120 of the chamber body 112 to the lower wall 122 of the chamber body 112. In certain examples, the first sidewall 124 and/or the second sidewall 126 may be substantially orthogonal relative to the upper wall 120 and/or the lower wall 122 of the chamber body 112. In accordance with certain examples, the chamber body 112 may include a plurality of external ribs 162 extending laterally about exterior surfaces of the chamber body 112 and laterally spaced apart from one another between the injection end 116 and the exhaust end 118 of the chamber body 112. It is also contemplated that the chamber body 112 may be formed from a ceramic material, such as quartz or sapphire by way of non-limiting examples.

The chamber arrangement 104 may also include a substrate support 130, a support member 132, a shaft member 134, and a divider 136. The divider 136 may be fixed within the interior 128 of the chamber body 112, divide the interior 128 of the chamber body 112 into an upper chamber 138 and a lower chamber 140, and define a divider aperture 142 therethrough fluidly coupling the lower chamber 140 of the chamber body 112 to the upper chamber 138 of the chamber body 112. The substrate support 130 (e.g., a susceptor) may be configured to support the substrate 2 during deposition of the material layer 4 onto the substrate 2 and in this respect may be arranged within the interior 128 of the chamber body 112 and supported for rotation R about a rotation axis 144. In further respect, the substrate support 130 may be at least partially in the divider aperture 142 and supported therein for rotation R about the rotation axis 144 and may be formed from an opaque material 146 (e.g., a material opaque to electromagnetic radiation within an infrared waveband). The support member 132 may be arranged within the lower chamber 140 of the chamber body 112 and along the rotation axis 144, may also be formed from the transparent material 114, and may be fixed in rotation relative to the substrate support 130. The shaft member 134 may extend from the support member 132 along the rotation axis 144 and through the lower wall 122 of the chamber body 112 and may be fixed in rotation relative to the support member 132. It is contemplated that the shaft member 134 may be formed from the transparent material 114, and that the shaft member 134 operably connect a lift and rotate module 148 to the substrate support 130. In certain examples, the opaque material 146 may include a carbonaceous material, such as graphite or pyrolytic carbon. In accordance with certain examples, the opaque material 146 may include a ceramic material, such as silicon carbide, and/or both a carbonaceous material like graphite and a ceramic material such as silicon carbide.

The chamber arrangement 104 may further include an injection flange 150, an exhaust flange 152, an upper heater element array 154, a lower heater element array 156, and a thermocouple 186. The injection flange 150 may abut the injection end 116 of the chamber body 112 and may couple to the precursor source 102 (shown in FIG. 1) to the chamber body 112 to provide the flow of the material layer precursor 10 to the chamber body 112. The exhaust flange 152 may abut the exhaust end 118 of the chamber body 112, couple the chamber body 112 to the exhaust source 106 (shown in FIG. 1), and be configured to communicate the flow or residual precursor and/or reaction products 14 (shown in FIG. 1) issued by the chamber arrangement 104 to the exhaust source 106.

The upper heater element array 154 may be configured to communicate heat into the interior 128 of the chamber body 112 (e.g., radiantly using infrared radiation in an infrared waveband) and in this respect is optically coupled to the interior 128 of the chamber body 112 by the upper wall 120 of the chamber body 112. It is contemplated that the upper heater element array 154 may include one or more upper heater element, for example a first upper heater element, a second upper heater element, and a third upper heater element each longitudinally separated from one another above the upper wall 120 of the chamber body 112. It is also contemplated that the upper heater element array 154 may separate an upper reflector 158 from the upper wall 120 of the chamber body 112 and be operably associated with the controller 108. In this respect the controller 108 may be configured to throttle (e.g., change by increasing or decreasing) heat generated by upper heater elements of the upper heater element array 154 and communicated into the interior 128 of the chamber arrangement 104. In further respect, the controller 108 may operably couple one or more upper pyrometer to the upper heater element array 154 to affect the aforementioned throttling of heat generated by the upper heater elements of the upper heater element array 154 using temperature measurements acquired by the one or more upper pyrometer.

The lower heater element array 156 may be similar to the upper heater element array 154 and additionally be supported below the lower wall 122 of the chamber body 112. The lower heater element array 156 may further separate a lower reflector 160 supported below the chamber body 112 from the lower wall 122 of the chamber body 112 and be configured to heat the substrate support 130 (and therethrough the substrate 2) using electromagnetic radiation communicated through the lower wall 122 of the chamber body 112. It is contemplated that the lower heater element array 156 be operably associated with the controller 108, and that the controller 108 in turn operably couple one of a lower pyrometer and a thermocouple to the lower heater element array 156 to throttle heat generated by lower heater elements of the lower heater element array 156 using temperature measurements acquired by the lower pyrometer or thermocouple.

The upper pyrometer 164 is configured to acquire a substrate temperature measurement 16 indicative of temperature of the substrate 2 and the material layer 4 during deposition onto the substrate 2. In this respect it is contemplated that the upper pyrometer 164 be supported above the upper wall 120 of the chamber body 112 and optically coupled to the interior 128 of the chamber body 112 along an upper pyrometer optical axis 168. It is contemplated that the upper pyrometer optical axis 168 may be coaxial with or radially offset from the rotation axis 144, facilitating packaging of the upper pyrometer 164 with the upper heater element array 154, and may be substantially parallel to the rotation axis 144. It is also contemplated that the upper pyrometer optical axis 168 may be substantially orthogonal relative the upper wall 120 and/or the lower wall 122 of the chamber body 112, and that that the upper pyrometer optical axis 168 intersect the substrate support 130 such that the upper pyrometer optical axis 168 intersects the substrate 2 when the substrate 2 is seated on the substrate support 130. It is further contemplated that the upper pyrometer 164 be operably coupled the upper heater element array 154, for example to throttle heating of the substrate 2 using the substrate temperature measurement 16 and a predetermined substrate temperature range. Operative coupling may be through the controller 108, the upper pyrometer 164 disposed in communication with controller 108 via the wired or wireless link 110. In certain examples of the present disclosure the upper pyrometer 164 may be as shown and described in U.S. Patent Application Publication No. 2022/0298643 A1 to Kajbafvala et al. filed on Mar. 17, 2022, the contents of which is incorporated herein by reference in its entirety. As will be appreciated by those skill in the art in view of the present disclosure, operably coupling of the upper pyrometer 164 with the upper heater element array 154 enables real-time temperature control of the substrate 2 and/or the material layer 4 during deposition there according to electromagnetic radiation emitted by the substrate 2 and/or the material layer 4 and received by the upper pyrometer 164 along the upper pyrometer optical axis 168. Examples of suitable pyrometers include OR400M series pyrometers, available from Advanced Energy Industries, Inc. of Denver, Colorado.

The lower pyrometer 166 is similar to the upper pyrometer 164 and is additionally configured to acquire a substrate support temperature measurement 18 of the substrate support 130. In this respect it is contemplated that the lower pyrometer 166 be supported below the chamber body 112 and optically coupled to the interior 128 of the chamber body 112 by the lower wall 122 of the chamber body 112 along a lower pyrometer optical axis 170. The lower pyrometer 166 may further by operably coupled with the lower heater element array 156, for example by the controller 108, to throttle heating of the substrate support 130 by the lower heater element array 156. In certain examples, the lower pyrometer 166 may be disposed in communication with the controller 108 via the wired or wireless link 110 to provide the non-contact substrate support temperature measurement 18 to the controller 108. Advantageously, inclusion of both the lower pyrometer 166 and the upper pyrometer 164 in the chamber arrangement 104 enables independent control of the upper heater element array 154 and the lower heater element array 156, for example by operably dissociating control of the upper heater element array 154 using the substrate temperature measurement 16 from control of the lower heater element array 156 using the non-contact substrate support temperature measurement 18 or the tactile substrate support temperature measurement 24, limiting (or eliminating) the effect the thermal mass of the substrate support 130 may have on control of temperature of the substrate 2.

It is contemplated that the lower pyrometer optical axis 170 intersect the substrate support 130, the lower pyrometer 166 thereby acquiring the non-contact substrate support temperature measurement 18 using electromagnetic radiation emitted by a lower surface of the substrate support 130 along the lower pyrometer optical axis 170. In certain examples, the lower pyrometer optical axis 170 may be substantially parallel to the rotation axis 144. In accordance with certain examples, the lower pyrometer optical axis 170 may be radially offset from the rotation axis 144, for example a location radially offset from the rotation axis 144 such that the lower pyrometer optical axis 170 is separated from the upper pyrometer optical axis 168 by the rotation axis 144. It is also contemplated that the lower pyrometer optical axis 170 may separate either (or both) the rotation axis 144 and the upper pyrometer optical axis 168 from the exhaust flange 152 or the injection flange 150 and remain with the scope of the present disclosure.

The thermocouple 186 may abut the substrate support 130 or be arranged within the substrate support 130, and be configured to acquire a tactile substrate support temperature measurement 24. The thermocouple 186 may be selectable to operably couple the thermocouple 186 to the lower heater element array 156, for example through the controller 108, to throttle heating of the substrate support 130 by the lower heater element array 156. In certain examples, the thermocouple 186 may be disposed in communication with the controller 108 via the wired or wireless link 110 to provide the tactile substrate support temperature measurement 24 to the controller 108. Advantageously, inclusion of both the thermocouple 186 and the upper pyrometer 164 in the chamber arrangement 104 enables selectable independent control of the upper heater element array 154 and the lower heater element array 156, for example by operably dissociating control of the upper heater element array 154 using the substrate temperature measurement 16 from control of the lower heater element array 156 using the tactile substrate support temperature measurement 24. As will be appreciated by those of skill in the art in view of the present disclosure, independent temperature control enables temperature control schemes that can compensate for thermal mass differences between the substrate 2 and the substrate support 130. As will also be appreciated by those of skill in the art in view of the present disclosure, selectable independent temperature control additionally enables control of the lower heater element array 156 according to sensitivity to the thermal mass of the substrate support 130. In certain examples, the thermocouple 186 may abut a lower surface of the substrate support 130 and be carried with the substrate support 130 in rotation about the rotation axis 144.

In certain examples, the upper pyrometer 164 may be a first upper pyrometer 164 arranged along a first upper pyrometer optical axis 168 and the chamber arrangement 104 may further include a second upper pyrometer 172 arranged along a second upper pyrometer optical axis 176. The second upper pyrometer 172 may be similar to the first upper pyrometer 164 and radially spaced apart from the first upper pyrometer 164. In this this respect it is contemplated that the second upper pyrometer 172 may be supported above the chamber body 112, optically coupled to the interior 128 of the chamber body 112 by the upper wall 120 of the chamber body 112, and configured to acquire a second substrate temperature measurement 20 using electromagnetic radiation emitted by the substrate 2 and/or the material layer 4 during deposition of the material layer 4 onto the substrate 2. The second upper pyrometer 172 may be operably coupled with the upper heater element array 154 and cooperate with the first upper pyrometer 164 to throttle heating of the substrate 2 during deposition of the material layer 4 onto the substrate 2. For example, the first upper pyrometer 164 may be operably coupled with a first upper heater element of the upper heater element array; e.g., one or more of the plurality of first upper heater elements 180 of the upper heater element array 154; and the second upper pyrometer 172 may be operably coupled to one or more of the plurality of second heater elements of the upper heater element array 154; e.g., to one or more of the plurality of second upper heater elements 184; arranged radially outward of the plurality of first upper heater elements 180.

The second upper pyrometer optical axis 176 may be radially offset from rotation axis 144, may also be radially offset from the first upper pyrometer optical axis 168, and may additionally be separated from the rotation axis 144 by the first upper pyrometer optical axis 168. The second upper pyrometer optical axis 176 may intersect the substrate support 130, for example at a location radially offset from either (or both) the rotation axis 144 and the first upper pyrometer optical axis 168, and that the second upper pyrometer optical axis 176 may be substantially parallel to either (or both) the rotation axis 144 and the first upper pyrometer optical axis 168. As will be appreciated by those of skill in the art in view of the present disclosure, examples including the second upper pyrometer 172 may acquire real-time temperature measurements of the substrate 2 and/or the material layer 4 during deposition thereon in concert with real-time temperature measurements acquired by the first upper pyrometer 164 at locations radially offset from where the first temperature measurements, e.g., the first substrate temperature measurement 16, enabling control of substrate processing parameters beyond substrate temperature. For example, in certain example of the present disclosure, the first substrate temperature measurement 16 and the second substrate temperature measurement 20 may be employed to control substrate center-to-edge temperature differences, for example by maintaining substrate center-to-edge temperature difference to within a predetermined substrate center-to-edge temperature difference range, limiting variation within the material layer 4 between the center and edge of the substrate 2. In certain examples the chamber arrangement 104 may be as shown and described in U.S. Patent Application Publication No. 2022/0301905 A1 to Ye et al., filed on Mar. 17, 2022, the contents of which are incorporated herein by reference in their entirety.

In certain examples of the present disclosure the chamber arrangement 104 may include a third upper pyrometer 174. The third upper pyrometer 174 may be similar to the first upper pyrometer 164 and operably coupled to the upper heater element array 154, for example to a third upper heater element, e.g., one or more of a plurality of third upper heater elements 182, radially intermediate the first upper heater element and the second upper heater elements. The third upper pyrometer 174 may be further configured to acquire a third substrate temperature measurement 22 of the substrate 2 and/or the material layer 4 during deposition of the material layer 4 onto the substrate 2. In this respect it is contemplated that the third upper pyrometer 174 may be optically coupled to the interior 128 of the chamber body 112 by a third upper pyrometer optical axis 178.

The third upper pyrometer optical axis 178 may be radially intermediate the first upper pyrometer optical axis 168 and the second upper pyrometer optical axis 176. The third upper pyrometer 174 may be operably coupled to one or more of a plurality of third upper heater elements 182 of the upper heater element array 154. The third upper pyrometer 174 may further be disposed in communication with the controller 108, for example via the wired or wireless link 110, to provide the third substrate temperature measurement 22 to the controller 108. As will be appreciated by those of skill in the art in view of the present disclosure, acquiring the third substrate temperature measurement 22 at a location radially intermediate locations on the substrate 2 from which the first substrate temperature measurement 16 and the second substrate temperature measurement 20 are acquired enables controlling cross-substrate temperature gradient in real-time, for example by determining a center-to-edge temperature function using substrate temperature measurements acquired by the first upper pyrometer 164, the second upper pyrometer 172, and the third upper pyrometer 174; determining slope of lines tangent to the center-to-edge temperature function; and comparing the greatest slope observed to a predetermined substrate temperature gradient range for purposes of determining whether, and if so, which, upper heater elements to throttle. In certain examples the third upper pyrometer 174 may be as shown and described in U.S. Patent Application Publication No. 2022/0298672 A1 to M'Saad et al., filed on Mar. 17, 2022,the contents of which is incorporated herein by reference in its entirety. Although shown and described herein as having specific numbers of upper pyrometers and lower pyrometers, it is to be understood and appreciated that chamber arrangements having additional or fewer upper pyrometers, and/or having additional lower pyrometers, may also benefit from the present disclosure.

It is contemplated that the controller 108 may be configured to receive substrate temperature measurements from one or more of the first upper pyrometer 164, the second upper pyrometer 172, and the third upper pyrometer 174. The controller 108 may furthermore be configured to throttle (e.g., change by increasing or decreasing) heat communicated by the upper heater element array 154 and the lower heater element array 156 into the chamber body 112. In certain examples a singular upper pyrometer, e.g., the first upper pyrometer 164, may be employed to control substrate temperature. In such examples temperature control may be accomplished by throttling the upper heater element array 154 by comparing the substrate temperature measurement 16 received from the first upper pyrometer 164 to a predetermined substrate temperature range and throttling heat generated by the upper heater element array 154 when the substrate temperature measurement 16 is outside of the predetermined substrate temperature range. In certain examples, only the upper heater element array 154 may be throttled when the substrate temperature measurement is outside of the predetermined substrate temperature range, heat output of the lower heater element array 156 remaining unchanged. In accordance with certain examples, heat output of both the upper heater element array 156 and the lower heater element array 154 may be throttled when the substrate temperature measurement 16 is outside of the predetermined substrate temperature range.

In certain examples, two or more upper pyrometers (e.g., the first upper pyrometer 164 and the second upper pyrometer 172) may be employed to control substrate temperature, substrate temperature control may be accomplished according to substrate center-to-edge temperature difference. In this respect a substrate center-to-edge temperature difference may be determined using the first substrate temperature measurement 16 and the second substrate temperature measurement 20, the substrate center-to-edge temperature difference compared to a predetermined substrate center-to-edge temperature difference range (e.g., recorded in one of the program modules 145 recorded on the memory 143), and one or more heater element of the upper heater element array 154 (e.g., one or more of the plurality of first upper heater elements 180 and/or one or more of the plurality of second upper heater elements 184) throttled when the substrate center-to-edge temperature difference is outside of the predetermined substrate center-to-edge temperature difference range. It is contemplated that, in certain examples, only the upper heater element array 154 may be throttled when the substrate center-to-edge temperature difference is outside of the predetermined substrate center-to-edge temperature difference range. It is also contemplated that both the upper heater element array 154 array the lower heater element array 156 may be throttled when the substrate center-to-edge temperature difference is outside of the predetermined substrate center-to-edge temperature difference range.

Furthermore, in examples wherein the chamber arrangement 104 includes the first upper pyrometer 164, the second upper pyrometer 172, and the third upper pyrometer 174, throttling may occur if a substrate center-to-edge temperature gradient determined using substrate temperature measurements acquired by the substrate pyrometers (e.g., determined using the first substrate temperature measurement 16, the second substrate temperature measurement 20, and the third substrate temperature measurement 22) differs from a predetermined substrate center-to-edge temperature gradient range. For example, a substrate center-to-edge gradient function may be determined using temperature measurements acquired by the each of the first upper pyrometer, the second upper pyrometer, and the third upper pyrometer using a curve fitting technique, slope of line tangent to the function determined at one or more location along the function, and the slope(s) compared to a predetermined substrate center-to-edge temperature gradient range, and heating of the substrate by the one upper heater element of the upper heater element array 154 throttled when the substrate center-to-edge temperature gradient is outside of a predetermined substrate center-to-edge temperature gradient range.

In the illustrated example the controller 108 includes a device interface 137, a processor 139, a user interface 141 and a memory 143. The device interface 137 may couple the processor 139 to the wired or wireless link 110 and therethrough to the one or more of the aforementioned devices of the semiconductor processing system 100 (shown in FIG. 1). The processor 139 may be operably connected to the user interface 141, for example to receive user input from user through the user interface 141 and/or provide user output to the user through the user interface 141 and is disposed in communication with the memory 143. The memory 143 may include a non-transitory machine-readable medium having a plurality of program modules 145 recorded thereon that, when read by the processor 139, cause the processor 139 to execute certain operations. Among the operations are operations of a material layer deposition method 300 (shown in FIG. 3), as will be described, and in respect the non-transitory machine-readable medium may be included in a computer program product 200 containing instructions in program modules 145 to execute the material layer deposition method 300. Although shown and described herein as having a specific architecture, it is to be understood and appreciated that the controller 108 may have a different architecture in other examples of the present disclosure, e.g., a distributed computing architecture, and remain within the scope of the present disclosure.

With reference to FIGS. 3-7, the material layer deposition method 300 is shown. Referring to FIG. 3, the material layer deposition method 300 generally includes seating a substrate on a substrate support, e.g., seating the substrate 2 (shown in FIG. 1) on the substrate support 130 (shown in FIG. 2), and heating the substrate to a predetermined material layer deposition temperature, as shown with box 302 and box 304. The material layer deposition method 300 also includes exposing the substrate to a material layer precursor and depositing a material layer onto the substrate using the material layer precursor, e.g., exposing the substrate to the material layer precursor 10 (shown in FIG. 1) and depositing the material layer 4 (shown in FIG. 1) onto the substrate, as shown box 306. The method further includes unseating the substrate from the substrate support subsequent to material layer deposition, as shown with box 307. Temperature of the substrate (i.e., substrate temperature) may be controlled using a substrate temperature measurement acquired by an upper pyrometer during deposition, e.g., the substrate temperature measurement 16 (shown in FIG. 2) acquired using the upper pyrometer 164 (shown in FIG. 2), as shown with box 310.

As shown with box 308, temperature of the substrate support (i.e., a substrate support temperature) may be controlled using a non-contact substrate support temperature measurement acquired using a lower pyrometer, e.g., the non-contact substrate support temperature measurement 18 (shown in FIG. 2) acquired by the lower pyrometer 166 (shown in FIG. 2). Alternatively (or additionally), temperature of the substrate support may be controlled using a tactile substrate support temperature measurement acquired by a thermocouple, e.g., the tactile substrate support temperature measurement 24 (shown in FIG. 2) acquired by the thermocouple 186 (shown in FIG. 2), as also shown with box 308. In this respect it is contemplated that the either lower pyrometer or the thermocouple may be selected to control temperature of the substrate during deposition of the material layer onto the substrate. Advantageously, controlling the substrate support temperature with a temperature control device other the upper pyrometer enables independent control of the substrate temperature relative to the substrate support temperature, for example but controlling temperature of the substrate to a different temperature than the substrate support, limiting the affect that the thermal mass of the substrate support may have on temperature of the substrate during material layer deposition and thereby variation of the material layer deposited onto the substrate.

Seating 302 the substrate within the chamber body may include opening a gate valve coupled to the chamber body 112 (shown in FIG. 2), as also shown with box 302. Seating 302 the substrate within the chamber body may include advancing an end effector into the chamber body using a substrate transfer robot, as further shown with box 302. Seating 302 the substrate within the chamber body may additionally include transferring the substrate into an interior of the chamber body, e.g., the interior 128 (shown in FIG. 2) of the chamber body, and thereafter withdrawing the end effector from within the interior of the chamber body and thereafter closing the gate valve, as also shown with box 302. In certain examples, seating 302 the substrate may include seating one and only one substrate within the chamber body, such as within a single-substrate chamber body having a crossflow architecture.

Heating 304 the substrate to the predetermined material layer deposition temperature may include radiantly communicating heat into the interior of the chamber body. In certain examples, the substrate may be heated to the predetermined material layer deposition temperature using radiant heat communicated by a plurality of upper heater elements supported above the chamber body, e.g., the plurality of upper heater elements of the upper heater element array 154 (shown in FIG. 2), as also shown with box 304. In accordance with certain examples, the substrate may be heated to the predetermined material layer deposition temperature using radiant heat communicated by a plurality of lower heater elements supported below the chamber body, e.g., the plurality of lower heater elements of the lower heater element array 156 (shown in FIG. 2), and conducted through the substrate support to the substrate, as further shown with box 304. In this respect the substrate may be heated to predetermined material layer deposition temperature using two or more of the plurality of upper linear lamps supported about the chamber in cooperation with the plurality of lower linear lamps supported below the chamber body, as additionally shown with box 304, and remain within the scope of the present disclosure.

Depositing 306 the material layer may include flowing a silicon-containing material into a chamber arrangement, e.g., the chamber arrangement 104 (shown in FIG. 1), as also shown with box 306. The silicon-containing material layer precursor may be flowed into an injection flange abutting the chamber body, e.g., the injection flange 150 (shown in FIG. 2), as also shown with box 306. Depositing 306 the material layer may include flowing silicon-containing material layer precursor through the chamber body to expose the substrate to the silicon-containing precursor, and thereafter communicating a flow of residual precursor and/or reaction products issued by the chamber arrangement through an exhaust flange abutting the chamber body to an exhaust source, e.g., through the exhaust flange 152 (shown in FIG. 2) to the exhaust source 106 (shown in FIG. 1), as also shown with box 306. In certain examples, the silicon-containing material layer precursor may include a non-chlorinated silicon-containing precursor, such as silane (SiH₄) or disilane (Si₂H₆). In accordance with certain examples, the silicon-containing material layer precursor may include a chlorinated silicon-containing material layer precursor, such as dichlorosilane (H₂SiCl₂).

In certain examples the silicon-containing material layer precursor may be co-flowed with a diluent or carrier gas. Examples of suitable diluent or carrier gases include hydrogen (H₂) gas, nitrogen (N₂) gas, and mixtures thereof. In accordance with certain examples, the silicon-containing material layer precursor may be co-flowed with an etchant, such as hydrochloric (HCl) acid and/or chlorine (Cl₂) gas. The silicon-containing material layer precursor may be co-flowed with an alloying constituent, such as germanium-containing material layer precursor like germane (GeH₄). It is further contemplated that the silicon-containing material layer precursor may be co-flowed with a dopant-containing material layer precursor, such as an n-type or a p-type dopant-containing material layer precursor. Examples of suitable dopant-containing material layer precursors include arsine (AsH₃), phosphine (PH₃), and diborane (B₂H₆). In certain examples, depositing 306 the material layer may include depositing an epitaxial material layer onto the substrate, such as a silicon-containing material layer. The silicon-containing material layer may include one or more of germanium (Ge) and a dopant, such as an n-type dopant or a p-type dopant.

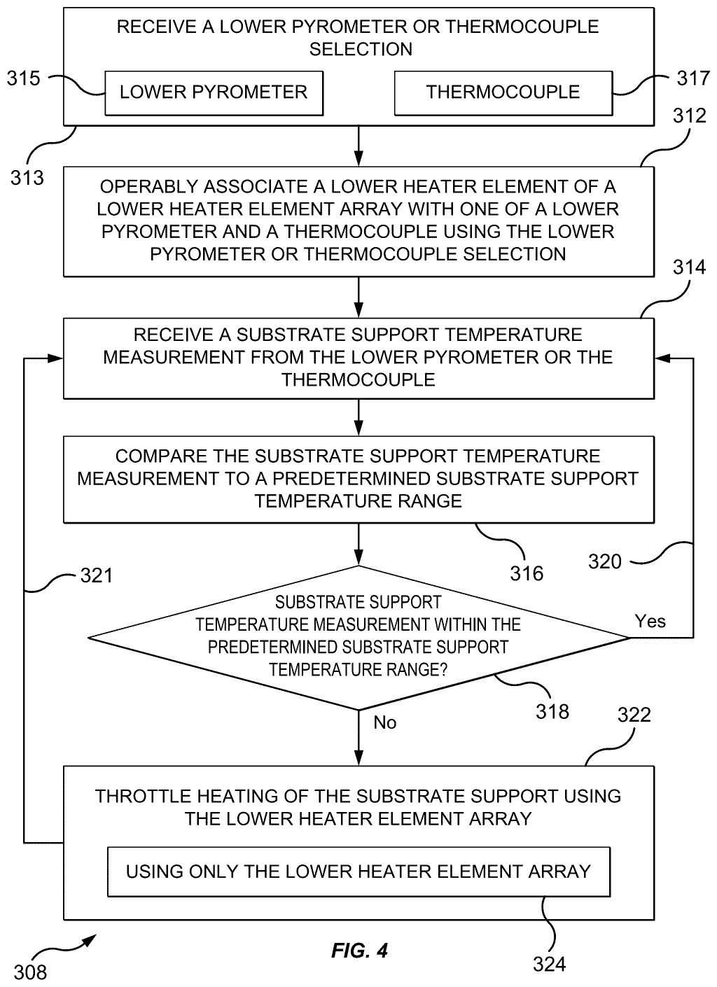

Referring to FIG. 4, controlling 308 substrate support temperature may include receiving a lower pyrometer selection or a thermocouple selection, as shown with box 313. In this respect it is contemplated that the lower pyrometer selection or thermocouple may be received at a user interface of a controller operatively connected to the chamber arrangement including the chamber body, e.g., the lower pyrometer selection or the thermocouple selection 26 (shown in FIG. 2 at the user interface 141 (shown in FIG. 2), as also shown with box 313. When the lower pyrometer selection or thermocouple selection is the lower pyrometer selection, the lower pyrometer may be operably coupled to one or more lower heater element of the lower heater element array, e.g., the lower pyrometer 166 (shown in FIG. 2) operably coupled to one or more lower heater element of the lower heater element array 156 (shown in FIG. 2), as shown with box 315 and box 312. When the lower pyrometer selection or thermocouple selection is the thermocouple selection, the thermocouple may be operably coupled to the one or more heater element of the lower heater element array, e.g., the thermocouple 186 (shown in FIG. 2), as also show with box 312. Operable coupling may be accomplished by a controller operatively connected to the lower heater element array and disposed in communication with the lower pyrometer and the thermocouple, e.g., the controller 108 (shown in FIG. 1), the controller thereby effecting control of temperature of the substrate support.

When the lower pyrometer selection or thermocouple selection 26 (shown in FIG. 2) is a lower pyrometer selection, control of the temperature of the substrate support may be accomplished by acquiring a non-contact substrate support temperature measurement using the lower pyrometer and communicating the non-contact substrate support temperature measurement to the controller, as shown with box 316. The controller may compare the non-contact substrate support temperature measurement to a predetermined substrate support temperature range, as shown with box 318, and heating of the substrate support by the lower heater element array throttled when the non-contact substrate support temperature measurement is outside of a predetermined substrate support non-contact temperature range, as shown with arrow 300 and box 322. Substrate support temperature may thereafter be rechecked, as shown with arrow 321. When the non-contact substrate support temperature measurement is within the predetermined substrate support non-contact temperature range, heating of the substrate support by the lower heater element array may remain unchanged, and temperature of the substrate support iteratively rechecked using the aforementioned operations, as also shown with box 318 and further shown with arrow 320. In certain examples, throttling of temperature of the substrate support using the lower heater element array may be accomplished only by the lower heater element array, heat output of the upper heater element remaining unchanged when the comparison indicates that the substrate support temperature measurement acquired by the lower pyrometer is outside of the predetermined substrate support non-contact temperature range, as shown with box 324.

When the lower pyrometer selection or thermocouple selection 26 (shown in FIG. 2) is a thermocouple selection, control of the temperature of the substrate support may be accomplished by acquiring a tactile substrate support temperature measurement using the thermocouple and communicating the tactile substrate support temperature measurement to the controller, as also shown with box 316. The controller may compare the tactile substrate support temperature measurement to a predetermined substrate support tactile temperature range, as also shown with box 318, and heating of the substrate support by the lower heater element array throttled when the tactile substrate support temperature measurement is outside of the predetermined substrate support tactile temperature range, as also shown with arrow 300 and box 322. When the tactile substrate support temperature measurement is within the predetermined substrate support tactile temperature range, heating of the substrate support by the lower heater element array may remain unchanged, and temperature of the substrate support iteratively rechecked also using the aforementioned operations, as also shown with box 318 and arrow 320. As above, throttling of the substrate support temperature using the lower heater element array when the thermocouple selection is selected may be accomplished only by the lower heater element array, heat output of the upper heater element remaining unchanged when the aforementioned comparison indicates that the non-contact substrate support temperature measurement acquired by the lower pyrometer is outside of the predetermined substrate support tactile temperature range, as also shown with box 324.

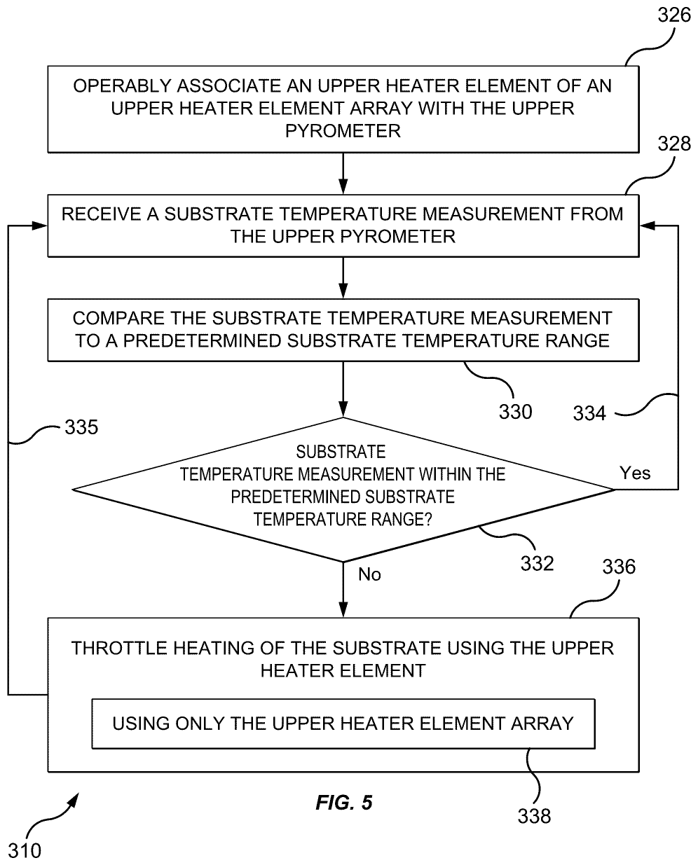

Referring to FIG. 5, controlling 310 substrate temperature may include operably coupling a singular upper pyrometer, e.g., the upper pyrometer 164 (shown in FIG. 2), to the upper heater element array, as shown with box 326. A substrate temperature measurement may be acquired by the upper pyrometer and communicated to the controller, e.g., the substrate temperature measurement 16 (shown in FIG. 2) communicated to the controller 108 (shown in FIG. 1), as shown with box 328. The controller may in turn compare the substrate temperature measurement to a predetermined substrate temperature range, as shown with box 330, and heating of the substrate by the upper heater element array throttled when the substrate temperature measurement is outside of the predetermined substrate temperature range, as shown with box 332 and box 336, and substrate temperature rechecked, as shown with arrow 335. When the substrate temperature measurement not outside of the predetermined substrate temperature range, heating of the substrate by the upper heater element array 154 may remain unchanged, as shown with arrow 334, and temperature monitoring continue iteratively using the aforementioned operations during deposition of the material layer onto the substrate.

In certain examples, throttling of temperature of the substrate using the upper heater element array may be accomplished only by the upper heater element array, as shown with box 338. In this respect it is contemplated that heating of the substrate support be independently controlled by the above-described comparing 318 (shown in FIG. 4) of the non-contact substrate support temperature measurement with the predetermined substrate support temperature range and throttling the lower heater element array, as appropriate, coincident and independent with the comparing 332 of the substrate temperature to the predetermined substrate temperature range to control temperature of the substrate. As will be appreciated by those of skill in the art in view of the present disclosure, independently controlling temperature of the substrate relative to temperature of the substrate support can limit the affect that the thermal mass of the substrate support could otherwise on temperature adjustment, for example in terms of time lag between when heating of the substrate support changes in response to change in heat output of the lower heater element array and when temperature of the substrate changes in response to change in the heat output of the lower heater element array. As will also be appreciated by those of skill in the art in view of the present disclosure, throttling of temperature of the substrate using only the upper heater element array also enables decreasing the interval between successively acquired substrate temperature measurement acquired by the upper pyrometer, increasing temperature adjustment accuracy possible in processes where real-time temperature monitoring may be employed to limit material layer variation.

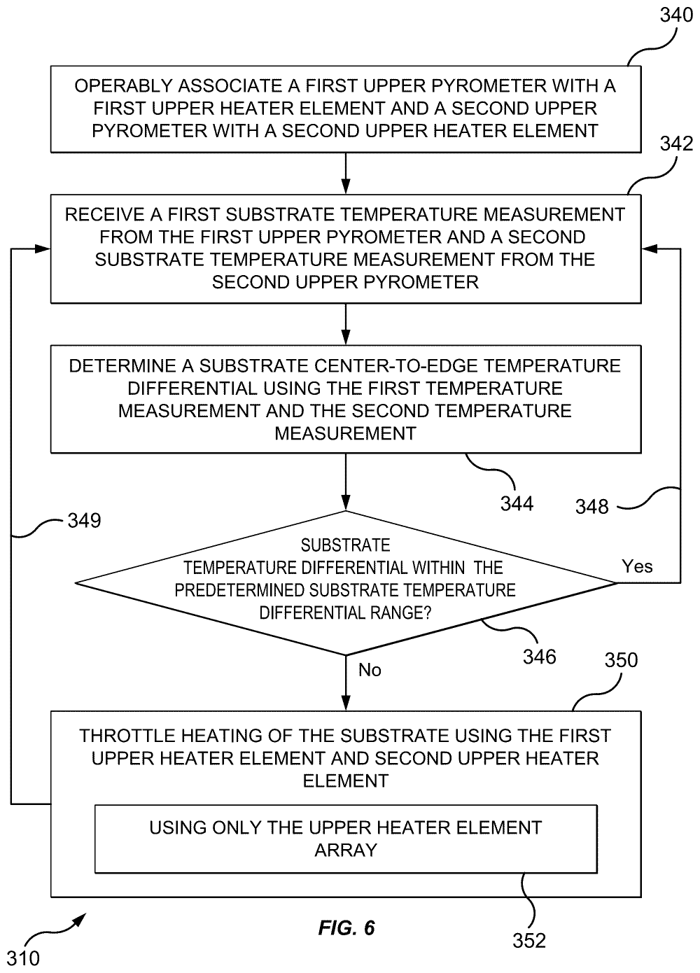

Referring to FIG. 6, controlling 310 substrate temperature may include operably coupling two (2) upper pyrometers to the upper heater element array, such as singular upper pyrometer, e.g., both a first upper pyrometer 164 (shown in FIG. 2) and a second upper pyrometer 172 (shown in FIG. 2), as shown with box 340. In this respect it is contemplated that both the first upper pyrometer and the second upper pyrometer may be disposed in communication with the controller, as also shown with box 340. The controller may in turn operably couple the first pyrometer to a first upper heater element of the upper heater element array and the second upper pyrometer to a second upper heater element of the upper heater element array, e.g., one or more of the plurality of first upper heater elements 180 (shown in FIG. 2) and the second upper pyrometer to one or more of the plurality of second upper heater elements 184 (shown in FIG. 2), as further shown with box 340. It is contemplated that the first upper pyrometer acquire a first substrate temperature measurement, e.g., the first substrate temperature measurement 16 (shown in FIG. 2), and that the first pyrometer communicate the first substrate temperature measurement to the controller, as shown with box 342. It is further contemplated that the second pyrometer acquire a second substrate temperature measurement, e.g., the second substrate temperature measurement 20 (shown in FIG. 2), and that the second pyrometer also communicate the second substrate temperature measurement to the controller, as also shown with box 342.

It is contemplated that the controller determine a substrate center-to-edge temperature difference using the first substrate temperature measurement and the second substrate temperature measurement, as shown with box 346. It is also contemplated that the controller may further throttle heating of the substrate using the upper heater element array when the substrate center-to-edge temperature difference is outside of a predetermined substrate center-to-edge temperature difference range, as shown with box 346 and box 350, for example by throttling one or more of the first upper heater element and the second upper heater element, as also shown with box 350. Temperature of the substrate may thereafter be rechecked using the aforementioned operations, as shown with arrow 349. It is further contemplated that substrate temperature difference monitoring continue when the substrate center-to-edge temperature difference is not outside of the predetermined substrate center-to-edge temperature difference range, as also shown with box 346 and further shown with arrow 348.

In certain examples, throttling of heating of the substrate to control substrate center-to-edge temperature difference may be accomplished using only the upper heater element array, as shown with box 352. In this respect it is contemplated that heating of the substrate support be independently controlled by the above-described comparing 318 (shown in FIG. 4) of the non-contact/tactile substrate support temperature measurement with the predetermined substrate support non-contact/tactile temperature range and throttling the lower heater element array, as appropriate, coincident and independent with the comparing 346 of the substrate center-to-edge temperature difference to the predetermined substrate center-to-edge temperature difference range to control temperature of the substrate. As will be appreciated by those of skill in the art in view of the present disclosure, independently controlling substrate center-to-edge temperature difference and substrate support temperature may improve accuracy of throttling adjustments made to heat output of the upper heater element array to control substrate center-to-edge temperature differences, for example, by avoiding the need to otherwise account for thermal mass of the substrate support when controlling substrate center-to-edge temperature differences using the lower heater element array.

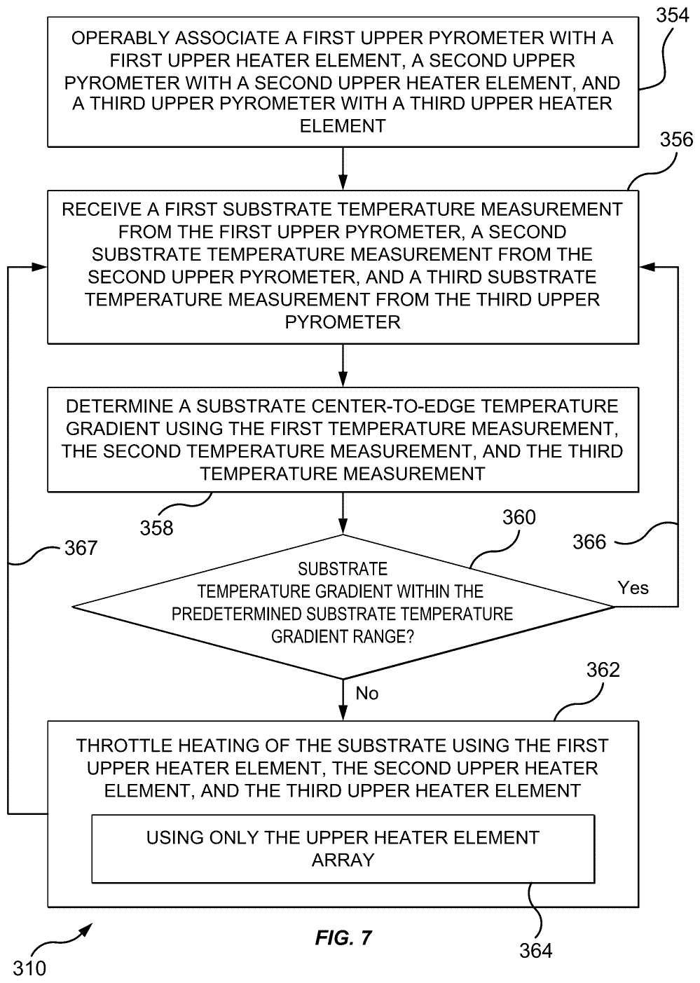

Referring to FIG. 7, controlling 310 substrate temperature may include operably coupling three (3) upper pyrometers to the upper heater element array; e.g., the first upper pyrometer 164 (shown in FIG. 2), the second upper pyrometer 172 (shown in FIG. 2), and the third upper pyrometer 174 (shown in FIG. 2), the separate heater elements of the upper heater element array, as shown with box 354. In this respect the first upper pyrometer may be operably coupled to a first upper heater element, e.g., one or more of the plurality of first upper heater elements 180 (shown in FIG. 2); the second upper pyrometer may be operably coupled to the second upper heater element, e.g., the one or more of the plurality of second upper heater elements 184 (shown in FIG. 2); and the one or more of the plurality of third upper heater elements 182 (shown in FIG. 2); as also shown with box 354. Operable coupling may be accomplished by a controller operably connected to the upper lamp array, e.g., the controller 108 (shown in FIG. 1), and in this respect it is contemplated that the first upper pyrometer, the second upper pyrometer, and the third pyrometer may coincidently acquire substrate temperature measurements from the substrate; e.g., the first substrate temperature measurement 16 (shown in FIG. 2), the second substrate temperature measurement 20 (shown in FIG. 2), and the third substrate temperature measurement 22 (shown in FIG. 2); and communicate the first substrate temperature measurement, the second substrate temperature measurement, and the third substrate temperature measurement to the controller, as also shown with box 354.

As shown with box 358, controlling 310 substrate temperature may include determining a substrate center-to-edge temperature gradient. In this respect the controller may receive the first substrate temperature measurement, the second substrate temperature measurement, the third substrate temperature measurement from the first upper pyrometer, the second upper pyrometer, and the third upper pyrometer, respectively, as shown with box 356. The controller may further determine a substrate center-to-edge temperature curve to the first temperature measurement, the second temperature measurement, and the third temperature measurement, as further shown with box 358, and thereafter determine the greatest slope of one more lines tangent to the determined center-to-edge temperature curve, for example one or more predetermined center-to-edge locations along the substrate center-to-edge temperature curve. The slope of the one or more line tangent to the center-to-edge temperature curve (e.g., a center-to-edge gradient) may be compared to a predetermined substrate center-to-edge temperature gradient range, and heating of the substrate using the upper heater element may be throttled using one or more of the first upper heater element, the second upper heater element, and the upper heater element based on the center-to-edge location of the line having slope outside of the predetermined substrate center-to-edge temperature gradient range, as shown with box 360 and box 362. Temperature control according by iteratively determining substrate center-to-edge temperature gradient may thereafter continue using the aforementioned operations as shown with arrow 367. Similarly, when substrate center-to-edge temperature gradient is within the predetermined substrate center-to-edge temperature gradient range, temperature control using the aforementioned operations may continue, as also shown with box 360 and arrow 366.

In certain examples, throttling of heating of the substrate to control substrate center-to-edge temperature gradient may be accomplished using only the upper heater element array, as shown with box 364. In this respect it is contemplated that heating of the substrate support be independently controlled by the above-described comparing 318 (shown in FIG. 4) of the non-contact substrate support temperature measurement with the predetermined substrate support temperature range and throttling the lower heater element array, as appropriate, coincident and independent with the comparing 360 the substrate center-to-edge temperature gradient to the predetermined substrate center-to-edge temperature gradient range to control temperature of the substrate. As will be appreciated by those of skill in the art in view of the present disclosure, controlling substrate center-to-edge temperature gradient and substrate support temperature independently may improve accuracy of throttling adjustments made to heat output of the upper heater element array to control substrate center-to-edge temperature gradient, for example, by avoiding the need to otherwise account for thermal mass of the substrate support when controlling center-to-edge temperature gradient using the lower heater element array.

Semiconductor processing systems employed for material layer deposition commonly employ temperature control devices. While generally satisfactory for their intended purpose, some temperature control devices may limit reliability and/or throughput of the semiconductor processing system, for example due to operating conditions within the process space within the semiconductor processing system as well as interactions with devices outside of the semiconductor processing system. In examples described herein semiconductor processing systems employ upper pyrometers and lower pyrometers for purposes of temperature control, limiting (or eliminating) the tendency of conditions within the process space and/or external devices to interfere with temperature control within the semiconductor processing system. In certain examples, the upper pyrometer may be employed to control direct heating of the substrate and the lower pyrometer may be employed to control indirect heating of the substrate, for example through a substrate support seating the substrate. In accordance with certain examples, more than one upper pyrometer may be employed to control direct heating of the substrate, for example, by heating the substrate using subsets of upper heater elements controlled by individual upper pyrometers.

Although this disclosure has been provided in the context of certain embodiments and examples, it will be understood by those skilled in the art that the disclosure extends beyond the specifically described embodiments to other alternative embodiments and/or uses of the embodiments and obvious modifications and equivalents thereof. In addition, while several variations of the embodiments of the disclosure have been shown and described in detail, other modifications, which are within the scope of this disclosure, will be readily apparent to those of skill in the art based upon this disclosure. It is also contemplated that various combinations or sub-combinations of the specific features and aspects of the embodiments may be made and still fall within the scope of the disclosure. It should be understood that various features and aspects of the disclosed embodiments can be combined with, or substituted for, one another in order to form varying modes of the embodiments of the disclosure. Thus, it is intended that the scope of the disclosure should not be limited by the particular embodiments described above.

The headings provided herein, if any, are for convenience only and do not necessarily affect the scope or meaning of the devices and methods disclosed herein.

1. A chamber arrangement, comprising:
a chamber body including a substrate support arranged therein and configured to seat thereon a substrate during deposition of a material layer onto the substrate;
an upper heater element array supported above the chamber body and configured to heat the substrate;
an upper pyrometer supported above the chamber body and operably coupled to the upper heater element array, the upper pyrometer configured to acquire a substrate temperature measurement of the substrate;
a lower heater element array supported below the chamber body and configured to heat the substrate support; and
a lower pyrometer supported below the chamber body and configured to acquire a non-contact substrate support temperature measurement.

2. The chamber arrangement of claim 1, further comprising a thermocouple abutting the substrate support and configured to acquire a tactile substrate support temperature measurement.

3. The chamber arrangement of claim 1, wherein the upper pyrometer is operably coupled to only the upper heater element array, and wherein the lower pyrometer is operably coupled to only the lower heater element array.

4. The chamber arrangement of claim 1, wherein the upper pyrometer is a first upper pyrometer and the substrate temperature measurement is a first substrate temperature measurement, and further comprising a second upper pyrometer supported above the chamber body configured to acquire a second substrate temperature measurement.

5. The chamber arrangement of claim 4, wherein the first upper pyrometer is optically coupled to an interior of the chamber body by a first upper pyrometer optical axis intersecting the substrate support, wherein the second upper pyrometer is optically coupled to the interior of the chamber body by a second upper pyrometer optical axis intersecting the substrate support, and wherein the lower pyrometer is arranged along a lower pyrometer optical axis intersecting the substrate support.

6. The chamber arrangement of claim 4, wherein the second upper pyrometer is operably coupled to only the upper heater element array, and wherein the lower pyrometer is operably coupled to only the lower heater element array.

7. The chamber arrangement of claim 4, further comprising a third upper pyrometer supported above the chamber body and configured to acquire a third substrate temperature measurement of the substrate.

8. The chamber arrangement of claim 7, wherein the third upper pyrometer is optically coupled to an interior of the chamber body by a third upper pyrometer optical axis intersecting the substrate support, wherein the lower pyrometer is arranged along a lower pyrometer optical axis intersecting the substrate at a location offset from the third upper pyrometer optical axis, and wherein the third pyrometer is radially intermediate the first pyrometer and the second pyrometer.

9. The chamber arrangement of claim 7, wherein the third upper pyrometer is operably coupled to only the upper heater element array, and wherein the lower pyrometer is operably coupled to only the lower heater element array.

10. A semiconductor processing system, comprising:
a chamber arrangement as recited in claim 1, wherein the lower pyrometer is selectable for operable coupling to the lower heater element array;
a thermocouple abutting the substrate support and configured to acquire a tactile substrate support temperature measurement, the thermocouple selectable for operable coupling to the lower heater element array; and
a controller operatively coupling the upper pyrometer to the upper heater element array and one of the lower pyrometer and the thermocouple to the lower heater element array, the controller responsive to instructions recorded on a memory to:
seat a substrate on the substrate support;
heat the substrate; and
deposit a material layer onto the substrate,
wherein temperature of the substrate is controlled using the substrate temperature measurement during deposition of the material layer onto the substrate,
wherein temperature of the substrate support is controlled using the non-contact substrate support temperature measurement during deposition of the material layer when the lower pyrometer is selected; and
wherein temperature of the substrate support is controlled using the tactile substrate support temperature measurement during deposition of the material layer when the thermocouple is selected.

11. The semiconductor processing system of claim 10, wherein the instructions further cause the controller to:
receive a lower pyrometer selection;
receive the non-contact substrate support temperature measurement from the lower pyrometer;
compare the non-contact substrate support temperature measurement to a predetermined substrate support non-contact temperature range; and
throttle heating of the substrate support using the lower heater element array when the non-contact substrate support temperature measurement is outside of the predetermined substrate support non-contact temperature range.

12. The semiconductor processing system of claim 10, wherein the instructions cause the controller to:
receive a thermocouple selection;
receive a tactile substrate support temperature measurement from the thermocouple;
compare the tactile substrate support temperature measurement to a predetermined substrate support tactile temperature range; and
throttle heating of the substrate support using the lower heater element array when the tactile substrate support temperature measurement is outside of the predetermined substrate support tactile temperature range.

13. The semiconductor processing system of claim 10, wherein the instructions further cause the controller to:
operably couple the upper pyrometer to a first upper heater element of the upper heater element array;
receive the substrate temperature measurement from the upper pyrometer;
compare the substrate temperature measurement to a predetermined substrate temperature range; and
throttle heating of the substrate using the first upper heater element when the substrate temperature measurement is outside of the predetermined substrate temperature range.

14. The semiconductor processing system of claim 10, wherein the upper pyrometer is a first upper pyrometer and the substrate temperature measurement is a first substrate temperature measurement, the semiconductor processing system further comprising a second upper pyrometer supported above the chamber body and disposed in communication with the controller, and wherein the instructions further cause the controller to:
operably couple the first upper pyrometer to a first upper heater element of the upper heater element array and the second pyrometer to a second upper heater element of the upper heater element array;
receive the first substrate temperature measurement from the first pyrometer and a second substrate temperature measurement from the second upper pyrometer;
determine a substrate center-to-edge temperature difference using the first substrate temperature measurement and the second substrate temperature measurement;
compare the substrate center-to-edge temperature difference to a predetermined substrate center-to-edge temperature difference range; and
throttle heating of the substrate using at least one of the first upper heater element and the second upper heater element of the upper heater element array when the substrate center-to-edge temperature difference is outside of the predetermined substrate center-to-edge temperature difference range.

15. The semiconductor processing system of claim 10, wherein the upper pyrometer is a first upper pyrometer and the substrate temperature measurement is a first substrate temperature measurement, the semiconductor processing system further comprising:
a second upper pyrometer supported above the chamber body and disposed in communication with the controller;
a third upper pyrometer supported above the chamber body and disposed in communication with the controller; and
wherein the instructions further cause the controller to:
operably couple the first upper pyrometer to a first upper heater element of the upper heater element array, the second pyrometer to a second upper heater element of the upper heater element array, and the third pyrometer to a third upper heater element of the upper heater element array;
receive a first substrate temperature measurement from the first pyrometer, a second substrate temperature measurement from the second upper pyrometer, and a third substrate temperature measurement from the third upper pyrometer;
determine a substrate center-to-edge temperature gradient using the first substrate temperature measurement, the second substrate temperature measurement and the third substrate temperature measurement;
compare the substrate center-to-edge temperature gradient to a predetermined substrate center-to-edge temperature gradient range; and
throttle heating of the substrate using at least one of the first upper heater element, the second upper heater element, and the third upper heater element of the upper heater element array when the substrate center-to-edge temperature gradient is outside of the predetermined substrate center-to-edge temperature gradient range.

16. A material layer deposition method, at a chamber arrangement including a chamber body including a substrate support arranged therein, an upper heater element array supported above the chamber body and configured to heat the substrate, an upper pyrometer supported above the chamber body and operably coupled to the upper heater element array, a lower heater element array supported below the chamber body; a lower pyrometer supported below the chamber body, and a thermocouple abutting the substrate support, the method comprising:
seating a substrate on the substrate support;
heating the substrate;
depositing a material layer onto the substrate;
controlling the substrate using a substrate temperature measurement acquired by the upper pyrometer during deposition of the material layer onto the substrate,
controlling temperature of the substrate support using a non-contact substrate support temperature measurement acquired by the lower pyrometer during deposition of the material layer onto the substrate when the lower pyrometer is selected, and
controlling temperature of the substrate support using a tactile substrate support temperature measurement acquired by the thermocouple during deposition of the material layer onto the substrate when the thermocouple is selected.

17. The method of claim 16, wherein the controlling temperature of the substrate support comprises:
receiving the lower pyrometer selection;
receiving a non-contact substrate support temperature measurement;
comparing the non-contact substrate support temperature measurement to a predetermined substrate support non-contact temperature range; and
throttling heating of the substrate support using the lower heater element array when the non-contact substrate support temperature measurement is outside of the predetermined substrate support non-contact temperature range.

18. The method of claim 16, further comprising wherein the controlling temperature of the substrate support comprises:
receiving a thermocouple selection;
receiving a tactile substrate support temperature measurement;
comparing the tactile substrate support temperature measurement to a predetermined substrate support tactile temperature range; and
throttling heating of the substrate support using the lower heater element array when the tactile substrate support temperature measurement is outside of the predetermined substrate support tactile temperature range.

19. The method of claim 16, wherein the controlling temperature of the substrate comprises:
operably coupling the upper pyrometer to a first upper heater element of the upper heater element array;
receiving the substrate temperature measurement from the upper pyrometer;
comparing the substrate temperature measurement to a predetermined substrate temperature range; and
throttling heating of the substrate using the first upper heater element when the substrate temperature measurement is outside of the predetermined substrate temperature range.

20. The method of claim 19, wherein the upper pyrometer is a first upper pyrometer and the substrate temperature measurement is a first substrate temperature measurement, the method further comprising:
operably coupling the first upper pyrometer to a first upper heater element of the upper heater element array and the second pyrometer to a second upper heater element of the upper heater element array;
receiving the first substrate temperature measurement from the first pyrometer and a second substrate temperature measurement from a second upper pyrometer;
determining a substrate center-to-edge temperature difference using the first substrate temperature measurement and the second substrate temperature measurement;
comparing the substrate center-to-edge temperature difference to a predetermined substrate center-to-edge temperature difference range; and
throttling heating of the substrate using at least one of the first upper heater element and the second upper heater element of the upper heater element array when the substrate center-to-edge temperature difference is outside of the predetermined substrate center-to-edge temperature difference range.

21. The method of claim 20, further comprising:
operably coupling a third pyrometer to a third upper heater element of the upper heater element array;
receiving a third substrate temperature measurement from the third upper pyrometer;
determining a substrate center-to-edge temperature gradient using the first substrate temperature measurement, the second substrate temperature measurement and the third substrate temperature measurement;
comparing the substrate center-to-edge temperature gradient to a predetermined substrate center-to-edge temperature gradient range; and
throttling heating of the substrate using at least one of the first upper heater element, the second upper heater element, and the third upper heater element of the upper heater element array when the substrate center-to-edge temperature gradient is outside of the predetermined substrate center-to-edge temperature gradient range.
